(19) United States
(12) Patent Application Publication
(10) Pub. No.: US 2019/0006356 A1
(43) Pub. Date: Jan. 3, 2019

(54) PACKAGE WITH EMBEDDED CAPACITORS

(71) Applicant: Intel Corporation, Santa Clara, CA (US)

(72) Inventors: Seok Ling Lim, Kulim (MY); Jenny Shio Yin Ong, Bayan Lepas (MY); Tin Poay Chuah, Bayan Lepas (MY); Hon Wah Chew, Seberang Perai Tengah (MY)

(73) Assignee: Intel Corporation, Santa Clara, CA (US)

(21) Appl. No.: 15/988,958

(22) Filed: May 24, 2018

(30) Foreign Application Priority Data
Jun. 29, 2017 (MY) PI2017702392

(51) Int. Cl. H01L 27/08; H01L 23/522; H01L 49/02

(52) U.S. Cl. CPC H01L 27/0805; H01L 28/40; H01L 23/5223

(57) ABSTRACT

An apparatus is provided which comprises: one or more dielectric layers forming a substrate, one or more first conductive contacts on a top surface of the substrate, one or more second conductive contacts on a bottom surface of the substrate opposite of the top surface, and one or more discrete capacitors conductively coupled with one or more of the first and second conductive contacts, the one or more discrete capacitors embedded within the substrate between the top surface and the bottom surface. Other embodiments are also disclosed and claimed.

### CLAIM OF PRIORITY

This application claims priority to Malaysian Patent Application No. PI2017702392, filed on 29 Jun. 2017, entitled “PACKAGE WITH EMBEDDED CAPACITORS”, and which is incorporated by reference in its entirety.

### BACKGROUND

Integrated circuit device package solutions generally include capacitors on the die side and/or the land side for power delivery. However, die side capacitors can be constrained by available package routing space and land side capacitors can be limited by socket space and ball pitch. Also, as devices and packages continue to shrink in size, the possibilities for capacitor type and real estate for capacitor placement becomes more problematic. Removing capacitors from device packages and placing them nearby on the associated printed circuit board would tend to complicate and increase board space requirements.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a cross-sectional view of a system with a package with embedded capacitors, according to some embodiments,

FIG. 2 illustrates a cross-sectional view of a system with a package with embedded capacitors, according to some embodiments,

FIG. 3 illustrates a cross-sectional view of a manufacturing step of a package substrate with embedded capacitors, according to some embodiments,

FIG. 4 illustrates a cross-sectional view of a manufacturing step of a package substrate with embedded capacitors, according to some embodiments,

FIG. 5 illustrates a cross-sectional view of a package substrate with embedded capacitors, according to some embodiments,

FIG. 6 illustrates a cross-sectional view of a manufacturing step of a package substrate with embedded capacitors, according to some embodiments,

FIG. 7 illustrates a cross-sectional view of a manufacturing step of a package substrate with embedded capacitors, according to some embodiments,

FIG. 8 illustrates a cross-sectional view of a package substrate with embedded capacitors, according to some embodiments,

FIG. 9 illustrates a flowchart of a method of forming a package with embedded capacitors, in accordance with some embodiments, and

FIG. 10 illustrates a smart device or a computer system or a SoC (System-on-Chip) which includes a package with embedded capacitors, according to some embodiments.

### DETAILED DESCRIPTION

Integrated circuit packages with embedded capacitors are generally presented. In this regard, embodiments of the present disclosure enable embedded capacitors that previously may have been located on a die side or a land side of a package. One skilled in the art would appreciate that these embedded capacitors may enable more conventional, less expensive surface mount capacitors. Additionally, embedded capacitors may provide better use of previously vacant space while being able to limit overall z-height of a system, which may be an important consideration in certain applications.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” “right,” “front,” “back,” “top,” “bottom,” “over,” “under,” and the like in the description and in the claims, if any, are used for descriptive purposes and not necessarily for describing permanent relative positions.

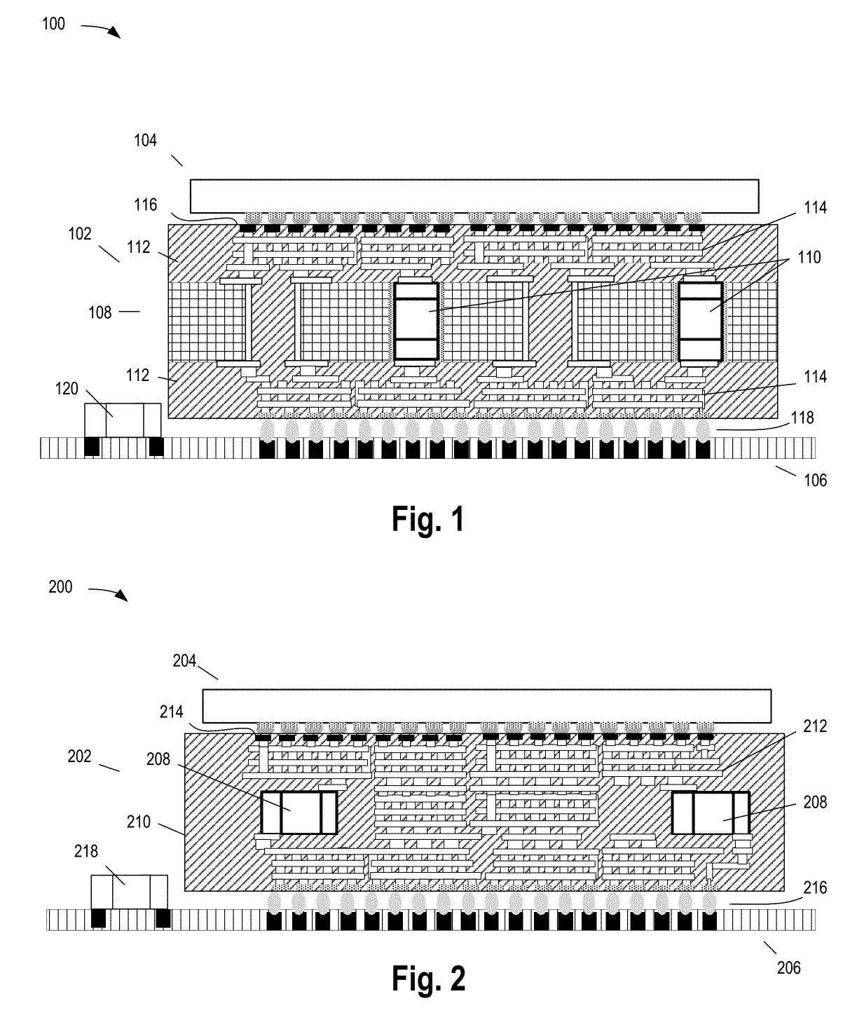

FIG. 1 illustrates a cross-sectional view of a system with a package with embedded capacitors, according to some embodiments. As shown, system 100 includes package substrate 102, integrated circuit die 104, system board 106, substrate core 108, embedded capacitors 110, dielectric material 112, conductive traces 114, substrate top contacts 116, substrate bottom contacts 118, and system board capacitor 120.

While shown as including a single die 104, system 100 can include multiple devices of similar or different types of integrated circuit devices. For example, die 104 can be any of application processors, graphics processors, field programmable gate arrays (FPGA), input/output (I/O) controllers, network controllers, or memory devices, among other devices. Die 104 is coupled with substrate top contacts 116 on a top surface of package substrate 102. Substrate bottom contacts 118 on a bottom surface of package substrate 102 (opposite of substrate top contacts 116) may enable package substrate 102 to be coupled with system board 106, which may include a printed circuit board, and may include ball grid array (BGA) or land grid array (LGA) contacts, for example.

Package substrate 102 may comprise a substrate core 108 surrounded by a dielectric material 112 with conductive traces 114, for example vertical and horizontal copper, or other conductive material, disposed therein. Embedded capacitors 110 may be embedded within substrate core 108 and be coupled with one or more of substrate top contacts 116 and substrate bottom contacts 118. In some embodiments, embedded capacitors 110 are discrete surface-mount device (SMD). In some embodiments, embedded capacitors 110 are standard 0402 metric (0.4 mm×0.2 mm) packages, though other size and types of capacitors may be used.

While shown as including vertical embedded capacitors 110 (with a long edge perpendicular to a top substrate surface), in some embodiments system 100 may also, or alternatively, include horizontal embedded capacitors 110 (with a long edge parallel to a top substrate surface). While shown as including two embedded capacitors 110, any number of embedded capacitors 110 may be included. Embedded capacitors 110 may, in some embodiments, be conductively coupled with system board capacitor 120, for example as part of a power delivery solution.

It should be appreciated that while discrete capacitors are described herein, other discrete components, such as resistors or inductors, for example, may be included instead of or in addition to discrete capacitors in various embodiments of the present disclosure.

FIG. 2 illustrates a cross-sectional view of a system with a package with embedded capacitors, according to some embodiments. As shown, system 200 includes package substrate 202, integrated circuit die 204, system board 206, embedded capacitors 208, dielectric material 210, conductive traces 212, substrate top contacts 214, substrate bottom contacts 216, and system board capacitor 218.

While shown as including a single die 204, system 200 can include multiple devices of similar or different types of integrated circuit devices. For example, die 204 can be any of application processors, graphics processors, field programmable gate arrays (FPGA), input/output (I/O) controllers, network controllers, or memory devices, among other devices. Die 204 is coupled with substrate top contacts 214 on top surface of package substrate 202. Substrate bottom contacts 216 on a bottom surface of package substrate 202 (opposite of substrate top contacts 214) may enable package substrate 202 to be coupled with system board 206, which may include a printed circuit board, and may include ball grid array (BGA) or land grid array (LGA) contacts, for example.

Package substrate 202 may comprise a dielectric material 210 with conductive traces 212, for example vertical and horizontal copper, or other conductive material, disposed therein. Embedded capacitors 208 may be coupled with one or more of substrate top contacts 214 and substrate bottom contacts 216. In some embodiments, embedded capacitors 208 are discrete surface-mount device (SMD). In some embodiments, embedded capacitors 208 is a standard 0402 metric (0.4 mm×0.2 mm) package, though other size and types of capacitors may be used.

While shown as including horizontal embedded capacitors 208 (with a long edge parallel to a top substrate surface), in some embodiments system 200 may also, or alternatively, include vertical embedded capacitors 208 (with a long edge perpendicular to a top substrate surface). While shown as including two embedded capacitors 208, any number of embedded capacitors 208 may be included. Embedded capacitors 208 may, in some embodiments, be conductively coupled with system board capacitor 218, for example as part of a power delivery solution.

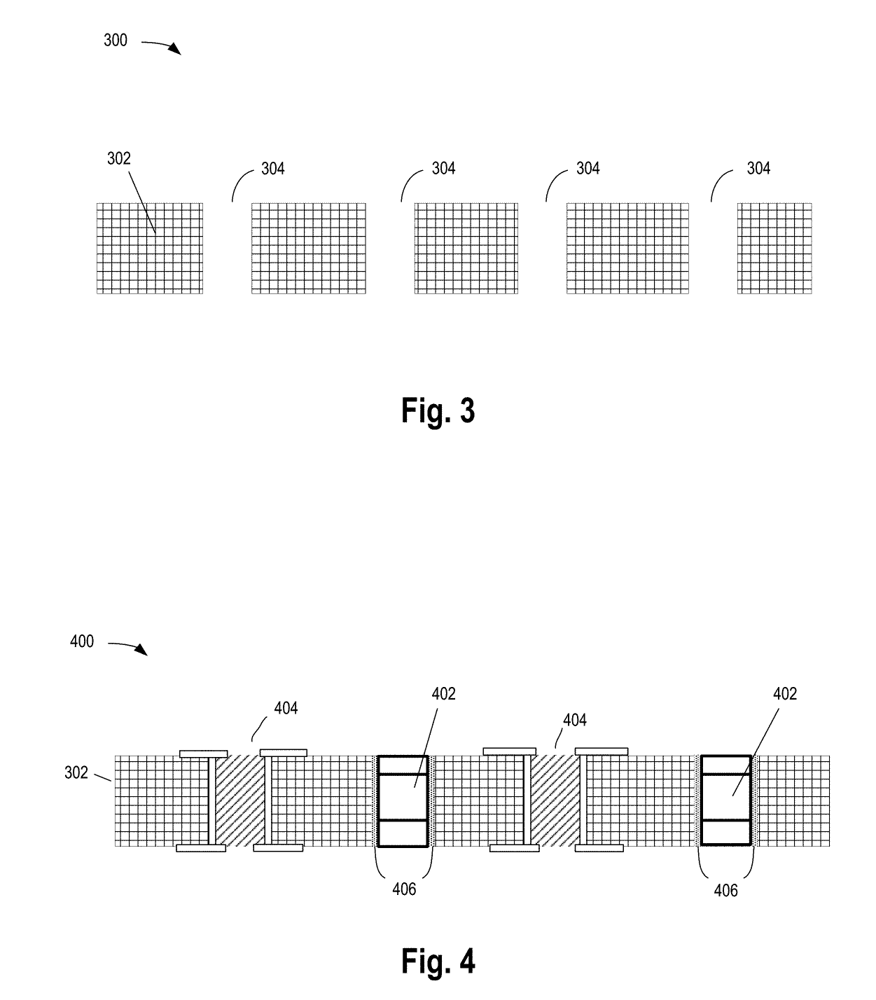

FIG. 3 illustrates a cross-sectional view of a manufacturing step of a package substrate with embedded capacitors, according to some embodiments. As shown, assembly 300 includes substrate core 302 and openings 304.

Substrate core 302 may be of any substance that provides mechanical stability, such as for example metal foil. Substrate core 302 may include insulator or conductor material. Substrate core 302 may include any number of openings 304. Openings 304 may be formed by mechanical or chemical means, such as for example drilling, laser ablation, or chemical etching. While shown as including openings 304 of substantially similar sizes, in some embodiments openings 304 are present in any number of various sizes.

FIG. 4 illustrates a cross-sectional view of a manufacturing step of a package substrate with embedded capacitors, according to some embodiments. As shown, assembly 400 includes substrate core 302, discrete capacitors 402, plated through holes 404, and adhesive 406. In some embodiments, discrete capacitors 402 include SMD capacitors, such as for example 0402 package capacitors, however any package size, including, for example 0201 metric packages may be used. Discrete capacitors 402 may be placed within openings of substrate core 302 with or without adhesive 406, and where adhesive 406 is included, discrete capacitors 402 may be placed before or after application of adhesive 406. In some embodiments, adhesive 406, which may include an epoxy or glue, may provide insulation, for example where substrate core 302 includes conductive metal. In some embodiments, plated through holes 404 are formed in substrate core 302 to include conductive walls that are filled with insulator material.

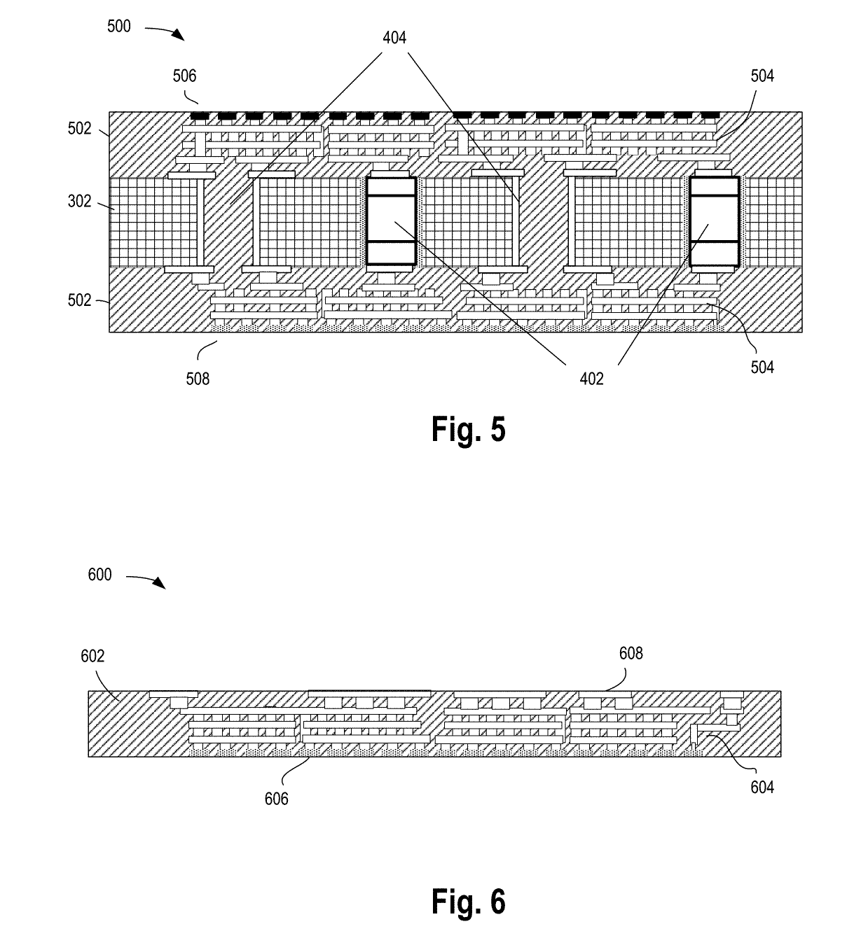

FIG. 5 illustrates a cross-sectional view of a package substrate with embedded capacitors, according to some embodiments. As shown, package substrate 500 includes substrate core 302, embedded capacitors 402, vias 404, dielectric layers 502, conductive features 504, top surface contacts 506, bottom surface contacts 508.

Dielectric layers 502 may be iteratively built-up upon substrate core 302 and embedded capacitors 402, for example by lamination or deposition, with the formation of conductive features 504 to form conductive contacts and interconnects. Conductive features 504 may conductively couple one terminal of embedded capacitors 402, and vias 404, to top surface contacts 506 and conductively couple an opposite terminal of embedded capacitors 402, and vias 404, to bottom surface contacts 508.

Additional processing steps may be performed on package substrate 500, for example to couple an integrated circuit die to top surface contacts 506 and/or to form BGA contacts on bottom surface contacts 508.

FIG. 6 illustrates a cross-sectional view of a manufacturing step of a package substrate with embedded capacitors, according to some embodiments. As shown, assembly 600 includes dielectric layers 602, conductive features 604, bottom surface contacts 606, and surface contacts 608.

Dielectric layers 602 may be iteratively built-up using known techniques, for example by lamination or deposition, with the formation of conductive features 604 to form conductive contacts and interconnects. Conductive features 604 may conductively couple surface contacts 608 to bottom surface contacts 606

FIG. 7 illustrates a cross-sectional view of a manufacturing step of a package substrate with embedded capacitors, according to some embodiments. As shown, assembly 700 includes dielectric layers 602, conductive features 604, bottom surface contacts 606, surface contacts 608, and discrete capacitors 702 with conductive terminals 704.

Discrete capacitors 702 may include a conductive terminal 704 that is placed in conductive contact with a surface contact 608. In some embodiments, discrete capacitors 702 may be soldered, glued or otherwise adhered in contact with surface contact 608. In some embodiments, conductive terminal 704 and surface contact 608 are adhered via conductive paste. In some embodiments, conductive paste is not separately included and may instead be built into conductive terminals 704.

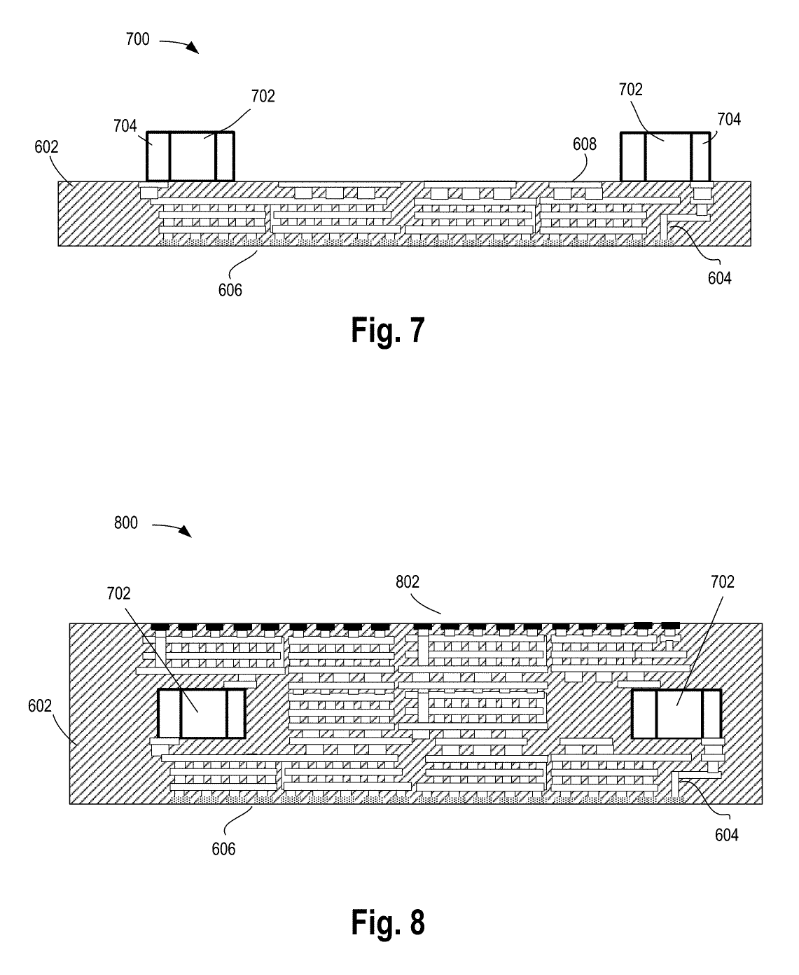

FIG. 8 illustrates a cross-sectional view of a package substrate with embedded capacitors, according to some embodiments. As shown, package substrate 800 includes embedded capacitors 702, dielectric layers 602, conductive features 604, top surface contacts 802, bottom surface contacts 606.

Dielectric layers 602 may be iteratively built-up upon embedded capacitors 702, for example by lamination or deposition, with the formation of conductive features 604 to form conductive contacts and interconnects. Conductive features 604 may conductively couple one terminal of embedded capacitors 702 to top surface contacts 802 and conductively couple an opposite terminal of embedded capacitors 702 to bottom surface contacts 606.

Additional processing steps may be performed on package substrate 800, for example to couple an integrated circuit die to top surface contacts 802 and/or to form BGA contacts on bottom surface contacts 606.

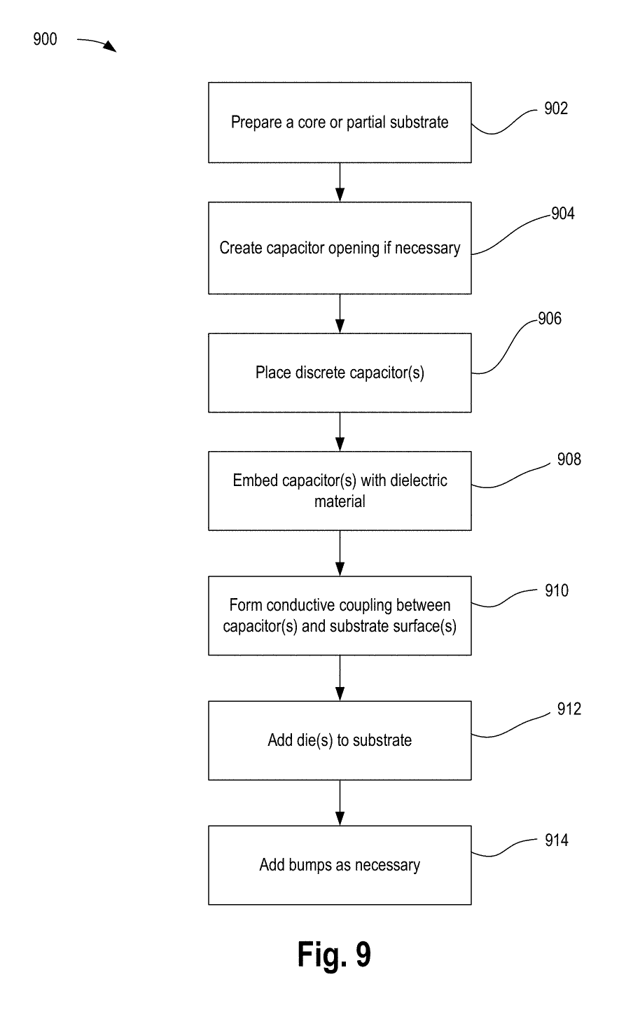

FIG. 9 illustrates a flowchart of a method of forming a package with embedded capacitors, in accordance with some embodiments. Although the blocks in the flowchart with reference to FIG. 9 are shown in a particular order, the order of the actions can be modified. Thus, the illustrated embodiments can be performed in a different order, and some actions/blocks may be performed in parallel. Some of the blocks and/or operations listed in FIG. 9 are optional in accordance with certain embodiments. The numbering of the blocks presented is for the sake of clarity and is not intended to prescribe an order of operations in which the various blocks must occur. Additionally, operations from the various flows may be utilized in a variety of combinations.

Method 900 begins with preparing (902) a substrate core or partial substrate. In some embodiments, a partial substrate such as assembly 600 may be prepared through deposition of dielectric material 602 and conductive features 604. In some embodiments, a substrate core material, such as substrate core 302 may be formed or unrolled, for example.

Next, capacitor openings may be created (904) if necessary. In some embodiments, openings 304 may be formed in substrate core 302 by mechanical or chemical means, such as for example drilling, laser ablation, or chemical etching.

Then, discrete capacitors may be placed (906). In some embodiments, discrete capacitors 402 may be placed in openings 304. In some embodiments, discrete capacitors 702 may be placed on a substrate surface with a terminal 704 in conductive contact with a substrate surface contact 608.

Next, the discrete capacitors may be embedded (908) with dielectric material. In some embodiments, layers of dielectric material (such as 502 or 602) are iteratively deposited along with formation of conductive features (such as 504 or 604). The method continues with forming (910) conductive couplings between the capacitors and substrate surfaces. In some embodiments, opposite terminals of the embedded capacitors are conductively coupled with contacts on opposite surfaces of the package substrate.

Next, one or more die may attached (912) to the package substrate. Finally, to the extent they are necessary, bumps, such as ball grid array (BGA) bumps, may be added (914) to the bottom of the package substrate.

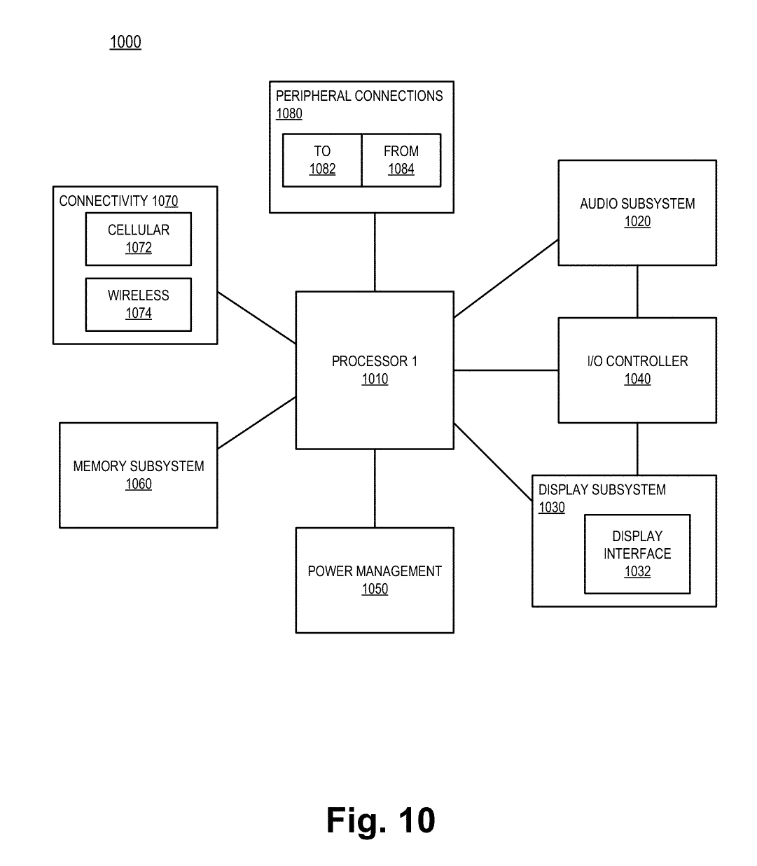

FIG. 10 illustrates a smart device or a computer system or a SoC (System-on-Chip) 1000 which includes a package with embedded capacitors, according to some embodiments. In some embodiments, computing device 1000 represents a mobile computing device, such as a computing tablet, a mobile phone or smart-phone, a wireless-enabled e-reader, or other wireless mobile device. It will be understood that certain components are shown generally, and not all components of such a device are shown in computing device 1000. In some embodiments, one or more components of computing device 1000, for example processor 1010 and/or memory subsystem 1060, are included in a package with embedded capacitors as described above.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Gate All Around Cylindrical Transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, etc., may be used without departing from the scope of the disclosure.

In some embodiments, computing device 1000 includes a first processor 1010. The various embodiments of the present disclosure may also comprise a network interface within 1070 such as a wireless interface so that a system embodiment may be incorporated into a wireless device, for example, cell phone or personal digital assistant.

In one embodiment, processor 1010 can include one or more physical devices, such as microprocessors, application processors, microcontrollers, programmable logic devices, or other processing means. The processing operations performed by processor 1010 include the execution of an operating platform or operating system on which applications and/or device functions are executed. The processing operations include operations related to I/O (input/output) with a human user or with other devices, operations related to power management, and/or operations related to connecting the computing device 1000 to another device. The processing operations may also include operations related to audio I/O and/or display I/O.

In one embodiment, computing device 1000 includes audio subsystem 1020, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 1000, or connected to the computing device 1000. In one embodiment, a user interacts with the computing device 1000 by providing audio commands that are received and processed by processor 1010.

Display subsystem 1030 represents hardware (e.g., display devices) and software (e.g., drivers) components that provide a visual and/or tactile display for a user to interact with the computing device 1000. Display subsystem 1030 may include display interface 1032, which may include the particular screen or hardware device used to provide a display to a user. In one embodiment, display interface 1032 includes logic separate from processor 1010 to perform at least some processing related to the display. In one embodiment, display subsystem 1030 includes a touch screen (or touch pad) device that provides both output and input to a user.

I/O controller 1040 represents hardware devices and software components related to interaction with a user. I/O controller 1040 is operable to manage hardware that is part of audio subsystem 1020 and/or display subsystem 1030. Additionally, I/O controller 1040 illustrates a connection point for additional devices that connect to computing device 1000 through which a user might interact with the system. For example, devices that can be attached to the computing device 1000 might include microphone devices, speaker or stereo systems, video systems or other display devices, keyboard or keypad devices, or other I/O devices for use with specific applications such as card readers or other devices.

As mentioned above, I/O controller 1040 can interact with audio subsystem 1020 and/or display subsystem 1030. For example, input through a microphone or other audio device can provide input or commands for one or more applications or functions of the computing device 1000. Additionally, audio output can be provided instead of, or in addition to display output. In another example, if display subsystem 1030 includes a touch screen, the display device also acts as an input device, which can be at least partially managed by I/O controller 1040. There can also be additional buttons or switches on the computing device 1000 to provide I/O functions managed by I/O controller 1040.

In one embodiment, I/O controller 1040 manages devices such as accelerometers, cameras, light sensors or other environmental sensors, or other hardware that can be included in the computing device 1000. The input can be part of direct user interaction, as well as providing environmental input to the system to influence its operations (such as filtering for noise, adjusting displays for brightness detection, applying a flash for a camera, or other features).

In one embodiment, computing device 1000 includes power management 1050 that manages battery power usage, charging of the battery, and features related to power saving operation. Memory subsystem 1060 may include memory devices for storing information in computing device 1000. Memory can include nonvolatile (state does not change if power to the memory device is interrupted) and/or volatile (state is indeterminate if power to the memory device is interrupted) memory devices. Memory subsystem 1060 can store application data, user data, music, photos, documents, or other data, as well as system data (whether long-term or temporary) related to the execution of the applications and functions of the computing device 1000.

Elements of embodiments are also provided as a machine-readable medium (e.g., memory 1060) for storing the computer-executable instructions. The machine-readable medium (e.g., memory 1060) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 1070 may include hardware devices (e.g., wireless and/or wired connectors and communication hardware) and software components (e.g., drivers, protocol stacks) to enable the computing device 1000 to communicate with external devices. The computing device 1000 could be separate devices, such as other computing devices, wireless access points or base stations, as well as peripherals such as headsets, printers, or other devices.

Connectivity 1070 can include multiple different types of connectivity. To generalize, the computing device 1000 is illustrated with cellular connectivity 1072 and wireless connectivity 1074. Cellular connectivity 1072 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 1074 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 1080 may include hardware interfaces and connectors, as well as software components (e.g., drivers, protocol stacks) to make peripheral connections. It will be understood that the computing device 1000 could both be a peripheral device (“to” 1082) to other computing devices, as well as have peripheral devices (“from” 1084) connected to it. The computing device 1000 commonly has a “docking” connector to connect to other computing devices for purposes such as managing (e.g., downloading and/or uploading, changing, synchronizing) content on computing device 1000. Additionally, a docking connector can allow computing device 1000 to connect to certain peripherals that allow the computing device 1000 to control content output, for example, to audiovisual or other systems.

In addition to a proprietary docking connector or other proprietary connection hardware, the computing device 1000 can make peripheral connections 1080 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

In one example, an apparatus is provided comprising: one or more dielectric layers forming a substrate; one or more first conductive contacts on a top surface of the substrate; one or more second conductive contacts on a bottom surface of the substrate opposite of the top surface; and one or more discrete capacitors conductively coupled with one or more of the first and second conductive contacts, the one or more discrete capacitors embedded within the substrate between the top surface and the bottom surface.

Some embodiments also include a substrate core within the dielectric layers. Some embodiments also include the one or more discrete capacitors embedded within the substrate core. Some embodiments also include the one or more discrete capacitors arranged with a longer edge perpendicular to the top and bottom surfaces. In some embodiments, the one or more discrete capacitors comprise a surface-mount device (SMD). In some embodiments, the one or more discrete capacitors comprises a 0402 package capacitor.

In another example, an apparatus is provided comprising: one or more integrated circuit die(s); and a substrate, wherein the substrate comprises: one or more dielectric layers forming a substrate; one or more first conductive contacts on a top surface of the substrate, the first conductive contacts coupled with the integrated circuit die(s); one or more second conductive contacts on a bottom surface of the substrate opposite of the top surface; and one or more discrete surface-mount device (SMD) capacitors conductively coupled with one or more of the first and second conductive contacts, the one or more discrete capacitors embedded within the substrate between the top surface and the bottom surface.

Some embodiments also include a substrate core within the dielectric layers, the one or more discrete capacitors embedded within the substrate core. In some embodiments, the substrate core comprises a metal. Some embodiments also include the one or more discrete capacitors arranged with a longer edge parallel to the top and bottom surfaces. Some embodiments also include the one or more discrete capacitors arranged with a longer edge perpendicular to the top and bottom surfaces. In some embodiments, the one or more discrete SMD capacitors comprises a 0402 package capacitor.

In another example, a system is provided comprising: a display subsystem; a wireless communication interface; and an integrated circuit package, the integrated circuit package comprising: one or more integrated circuit die(s); and a substrate coupled with the die(s), wherein the substrate comprises: one or more dielectric layers forming a substrate; one or more first conductive contacts on a top surface of the substrate, the first conductive contacts coupled with the integrated circuit die(s); one or more second conductive contacts on a bottom surface of the substrate opposite of the top surface; and one or more discrete capacitors conductively coupled with one or more of the first and second conductive contacts, the one or more discrete capacitors embedded within the substrate between the top surface and the bottom surface.

Some embodiments also include a substrate core within the dielectric layers, the one or more discrete capacitors embedded within the substrate core. In some embodiments, the substrate core comprises a metal. Some embodiments also include the one or more discrete capacitors arranged with a longer edge perpendicular to the top and bottom surfaces. In some embodiments, the one or more discrete capacitor(s) comprise a surface-mount device (SMD). In some embodiments, the one or more discrete capacitor(s) comprises a 0402 package capacitor.

In another example, a method is provided comprising: forming one or more dielectric layers of a substrate; forming one or more first conductive contacts on a top surface of the substrate; forming one or more second conductive contacts on a bottom surface of the substrate opposite of the top surface; and embedding one or more discrete surface-mount device (SMD) capacitors within the substrate between the top surface and the bottom surface, including conductively coupling the one or more discrete SMD capacitors with one or more of the first and second conductive contacts.

In some embodiments, embedding one or more discrete SMD capacitors within the substrate comprises: forming an opening in a substrate core; and placing a discrete SMD capacitor in the opening. In some embodiments, the substrate core includes a metal, wherein forming an opening in the substrate core comprises insulating the opening. In some embodiments, embedding one or more discrete SMD capacitors within the substrate comprises: placing a discrete SMD capacitor on a first dielectric layer surface; and forming a second dielectric layer around the SMD capacitor. In some embodiments, placing a discrete SMD capacitor on a first dielectric layer surface comprises placing the discrete SMD capacitor such that a first terminal is in contact with a conductive trace in the first dielectric layer surface. In some embodiments, embedding one or more discrete capacitors within the substrate comprises embedding one or more discrete capacitors with a longer edge perpendicular to the top and bottom surfaces. In some embodiments, embedding one or more discrete capacitors within the substrate comprises embedding a 0402 package capacitor.

In another example, an integrated circuit device package with embedded capacitors is presented comprising: means of forming a substrate; a plurality of first conductive means to couple with a die on a top surface of the substrate; a plurality of second conductive means to couple with a printed circuit board on a bottom surface of the substrate; one or more discrete capacitors conductively coupled with one or more of the first and second conductive means, the one or more discrete capacitors embedded within the substrate between the top surface and the bottom surface.

In some embodiments, the means for forming a substrate comprises a substrate core. Some embodiments also include the one or more discrete capacitor(s) embedded in openings within substrate core. Some embodiments also include the one or more discrete capacitor(s) arranged perpendicularly to the top surface and the bottom surface. In some embodiments, the one or more discrete capacitor(s) comprise a surface-mount device (SMD). In some embodiments, the one or more discrete capacitor(s) comprise a 0402 package capacitor.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. An apparatus comprising:
one or more dielectric layers forming a substrate;
one or more first conductive contacts on a top surface of the substrate;
one or more second conductive contacts on a bottom surface of the substrate opposite of the top surface; and
one or more discrete capacitors conductively coupled with one or more of the first and second conductive contacts, the one or more discrete capacitors embedded within the substrate between the top surface and the bottom surface.

2. The apparatus of claim 1, further comprising a substrate core within the dielectric layers.

3. The apparatus of claim 2, further comprising the one or more discrete capacitors embedded within the substrate core.

4. The apparatus of claim 1, further comprising the one or more discrete capacitors arranged with a longer edge perpendicular to the top and bottom surfaces.

5. The apparatus of claim 1, wherein the one or more discrete capacitors comprise a surface-mount device (SMD).

6. The apparatus of claim 1, wherein the one or more discrete capacitors comprises a 0402 package capacitor.

7. An apparatus comprising:
one or more integrated circuit die(s); and
a substrate, wherein the substrate comprises:
one or more dielectric layers forming a substrate;
one or more first conductive contacts on a top surface of the substrate, the first conductive contacts coupled with the integrated circuit die(s);
one or more second conductive contacts on a bottom surface of the substrate opposite of the top surface; and
one or more discrete surface-mount device (SMD) capacitors conductively coupled with one or more of the first and second conductive contacts, the one or more discrete capacitors embedded within the substrate between the top surface and the bottom surface.

8. The apparatus of claim 7, further comprising a substrate core within the dielectric layers, the one or more discrete capacitors embedded within the substrate core.

9. The apparatus of claim 8, wherein the substrate core comprises a metal.

10. The apparatus of claim 8, further comprising the one or more discrete capacitors arranged with a longer edge parallel to the top and bottom surfaces.

11. The apparatus of claim 8, further comprising the one or more discrete capacitors arranged with a longer edge perpendicular to the top and bottom surfaces.

12. The apparatus of claim 8, wherein the one or more discrete SMD capacitors comprises a 0402 package capacitor.

13. A system comprising:
a display subsystem;
a wireless communication interface; and
an integrated circuit package, the integrated circuit package comprising:
one or more integrated circuit die(s); and
a substrate coupled with the die(s), wherein the substrate comprises:
one or more dielectric layers forming a substrate;
one or more first conductive contacts on a top surface of the substrate, the first conductive contacts coupled with the integrated circuit die(s);
one or more second conductive contacts on a bottom surface of the substrate opposite of the top surface; and
one or more discrete capacitors conductively coupled with one or more of the first and second conductive contacts, the one or more discrete capacitors embedded within the substrate between the top surface and the bottom surface.

14. The system of claim 13, further comprising a substrate core within the dielectric layers, the one or more discrete capacitors embedded within the substrate core.

15. The system of claim 14, wherein the substrate core comprises a metal.

16. The system of claim 13, further comprising the one or more discrete capacitors arranged with a longer edge perpendicular to the top and bottom surfaces.

17. The system of claim 13, wherein the one or more discrete capacitor(s) comprise a surface-mount device (SMD).

18. The system of claim 13, wherein the one or more discrete capacitor(s) comprises a 0402 package capacitor.

19. A method comprising:
forming one or more dielectric layers of a substrate;
forming one or more first conductive contacts on a top surface of the substrate;
forming one or more second conductive contacts on a bottom surface of the substrate opposite of the top surface; and
embedding one or more discrete surface-mount device (SMD) capacitors within the substrate between the top surface and the bottom surface, including conductively coupling the one or more discrete SMD capacitors with one or more of the first and second conductive contacts.

20. The method of claim 19, wherein embedding one or more discrete SMD capacitors within the substrate comprises:
forming an opening in a substrate core; and
placing a discrete SMD capacitor in the opening.

21. The method of claim 20, wherein the substrate core includes a metal, wherein forming an opening in the substrate core comprises insulating the opening.

22. The method of claim 21, wherein embedding one or more discrete SMD capacitors within the substrate comprises:
placing a discrete SMD capacitor on a first dielectric layer surface; and
forming a second dielectric layer around the SMD capacitor.

23. The method of claim 22, wherein placing a discrete SMD capacitor on a first dielectric layer surface comprises placing the discrete SMD capacitor such that a first terminal is in contact with a conductive trace in the first dielectric layer surface.

24. The method of claim 22, wherein embedding one or more discrete capacitors within the substrate comprises embedding one or more discrete capacitors with a longer edge perpendicular to the top and bottom surfaces.

25. The method of claim 22, wherein embedding one or more discrete capacitors within the substrate comprises embedding a 0402 package capacitor.
